(19) United States
(12) Patent Application Publication
(10) Pub. No.: US 2009/0273903 A1
(43) Pub. Date: Nov. 5, 2009

(54) Installation structure for a fan

(76) Inventor: Yen-Wen Su, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/149,415

(22) Filed: May 1, 2008

(51) Int. Cl. H05K 7/20

(52) U.S. Cl. 361/695

(57) ABSTRACT

An installation structure for a fan includes a housing, a fastening frame, and a protection structure. The housing has an opening. The fastening frame is combined with the housing and has a fan receiving area. The fan receiving area links to the opening. The protection structure is combined with the fastening frame. Thereby, after the user disassembled the fan from the fastening frame, it can prevent the electronic components in the housing from being damaged due to external force.

### BACKGROUND OF THE INVENTION

1. Field of the Invention

The present invention relates to an installation structure for a fan. In particular, this invention relates to an installation structure for a fan that has a protection structure to protect the electronic components located in the device.

2. Description of the Related Art

The installation structure for a fan of the prior art, such as Taiwan patent application number TW 95116409, includes a housing having an opening, and a fastening frame combined with the housing and having a receiving area. The fan receiving area links to the opening.

However, after the fan is disassembled from the fan receiving area of the fastening frame, the fan receiving area is hollow so that dust enters into the housing to affect the functions of electronic components in the housing. Moreover, the user also may accidentally touch the electronic components in the housing, and maybe hurt.

### SUMMARY OF THE INVENTION

One particular aspect of the present invention is to provide an installation structure for a fan that has a protection structure. After the user disassembles the fan, it prevents the electronic components in the housing from being damaged due to external force.

The installation structure for a fan includes a housing having an opening, a fastening frame combined with the housing and having a receiving area, and a protection structure combined with the fastening frame. The fan receiving area links to the opening.

For further understanding of the invention, reference is made to the following detailed description illustrating the embodiments and examples of the invention. The description is for illustrative purpose only and is not intended to limit the scope of the claim.

### BRIEF DESCRIPTION OF THE DRAWINGS

The drawings included herein provide a further understanding of the invention. A brief introduction of the drawings is as follows:

FIG. 1 is an assembled perspective view of the first embodiment of the present invention;

FIG. 2 is an exploded perspective view of the first embodiment of the present invention;

FIG. 3 is an exploded perspective view of the second embodiment of the present invention;

FIG. 4 is an exploded perspective view of the third embodiment of the present invention; and

FIG. 5 is an exploded perspective view of the fourth embodiment of the present invention.

### DETAILED DESCRIPTION OF THE PREFERRED EMBODIMENTS

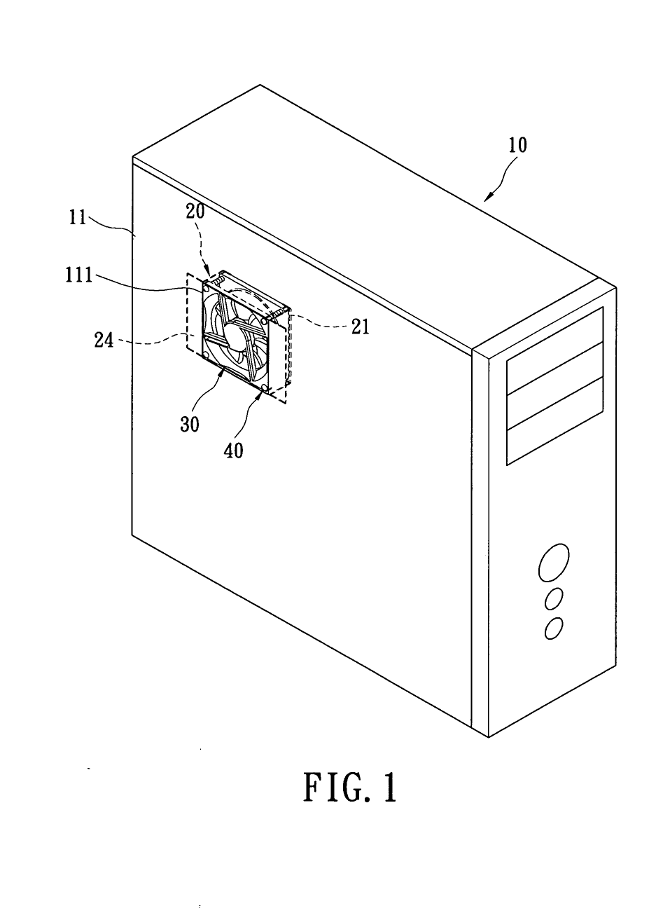

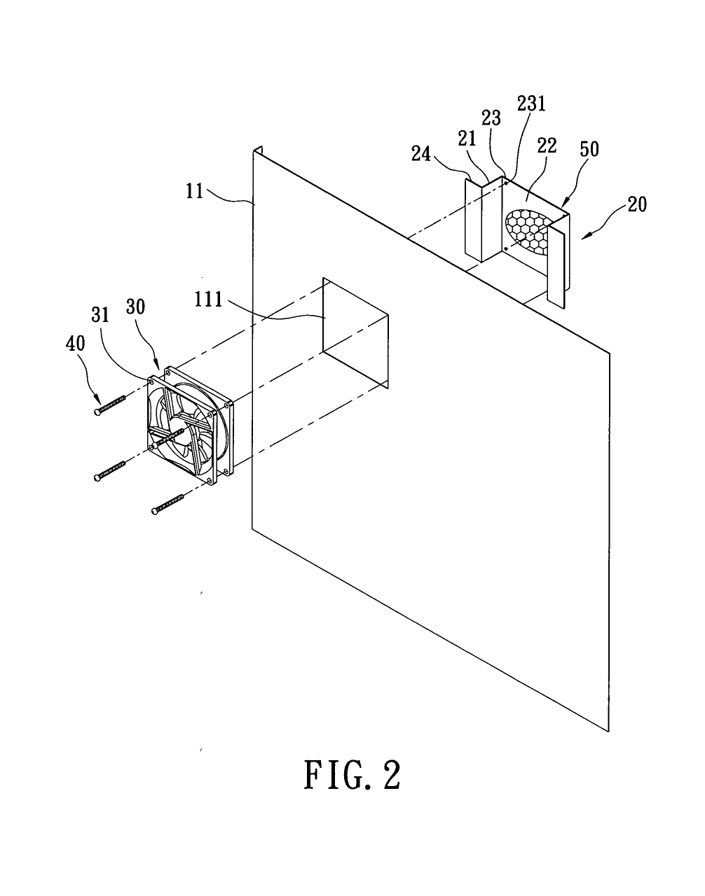

Reference is made to FIGS. 1 and 2, which show the installation structure for a fan of the first embodiment of the present invention. The installation structure for a fan includes a housing 10, a fastening frame 20, a fan 30, and a protection structure 50.

The housing 10 is a power supply housing, a backup power supply housing, a personal computer housing, industrial computer housing, a server housing, a UPS housing, an external redundant array of independent disk housing, an external hard disk housing, an external optical drive housing, a keyboard housing, a laptop cooling board housing, a projector housing, a medical measurement test equipment housing, or housing of other devices with a fan. In this embodiment, the housing 10 is a housing of a personal computer. The housing 10 includes a side board 10. There is a square opening 111 located at outside of the side board 11. The opening 111 links the interior of the housing 10.

The fastening frame 20 is a board body and has two blocking walls 21. The two blocking walls 21 are opposite to each other and are disposed at an interval. Between the two blocking walls 21, there is a fan receiving area 22 for receiving the fan 30. The fan receiving area 22 links the opening 111.

The rear side of each of the blocking walls 21 is connected with an installation portion 23. The installation portion 23 is located in the fan receiving area 22, and each of the upper side and the lower side of the installation portion 23 has a screw hole 231 for installing the fan 30.

The front side of each of the blocking walls 21 is connected with a fastening portion 24. The fastening portions 24 are located at the inner surface of the side board 11, and are close to the left side and right side of the opening 111. The two fastening portions 24 is connected to the inner surface of the side board 11 via a spot-welding method, a riveting method, or a locking method so that the fastening frame 20 is fastened to the housing 10.

The fan 30 is an axial-flow fan, a centrifugal fan or a cross flow fan. In this embodiment, the fan 30 is an axial-flow fan. Each of the four corners of the fan 30 has a circular through hole 31 for fastening the fan 30.

The protection structure 50 is combined with the fastening frame 20. In this embodiment, the protection structure 50 is a filtering screen. The filtering screen is integrated with the fastening frame 20 into one piece. Alternatively, the filtering screen is an independent element and is assembled to the fastening frame 20 (not shown in the figure).

When the fan 30 is installed, the fan 30 passes through the opening 111 and is received in the fan receiving area 22 of the fastening frame 20, and four screws 40 respectively pass through the four through holes 31 of the fan 30 to screw the fan 30 onto the screw holes 231 of the installation portion 23. Thereby, the fan 30 is locked to the fastening frame 20, and the fan 30 is installed at the housing 10 via the opening.

When the fan 30 is disassembled, the four screws 40 located at the four corners of the fan 30 are leased via the opening 111 to unlock the fan 30 from the fastening frame 20. Thereby, the fan 30 can be moved out from the fastening frame 20, and the fan 30 is disassembled from the housing 10 via the opening 111.

After the fan 30 is disassembled from the housing 10, the protection structure 30 (the filtering screen) can prevent dust from entering into the housing 10, and prevent the user from touching the electronic components in the housing to hurt the user or damage the device.

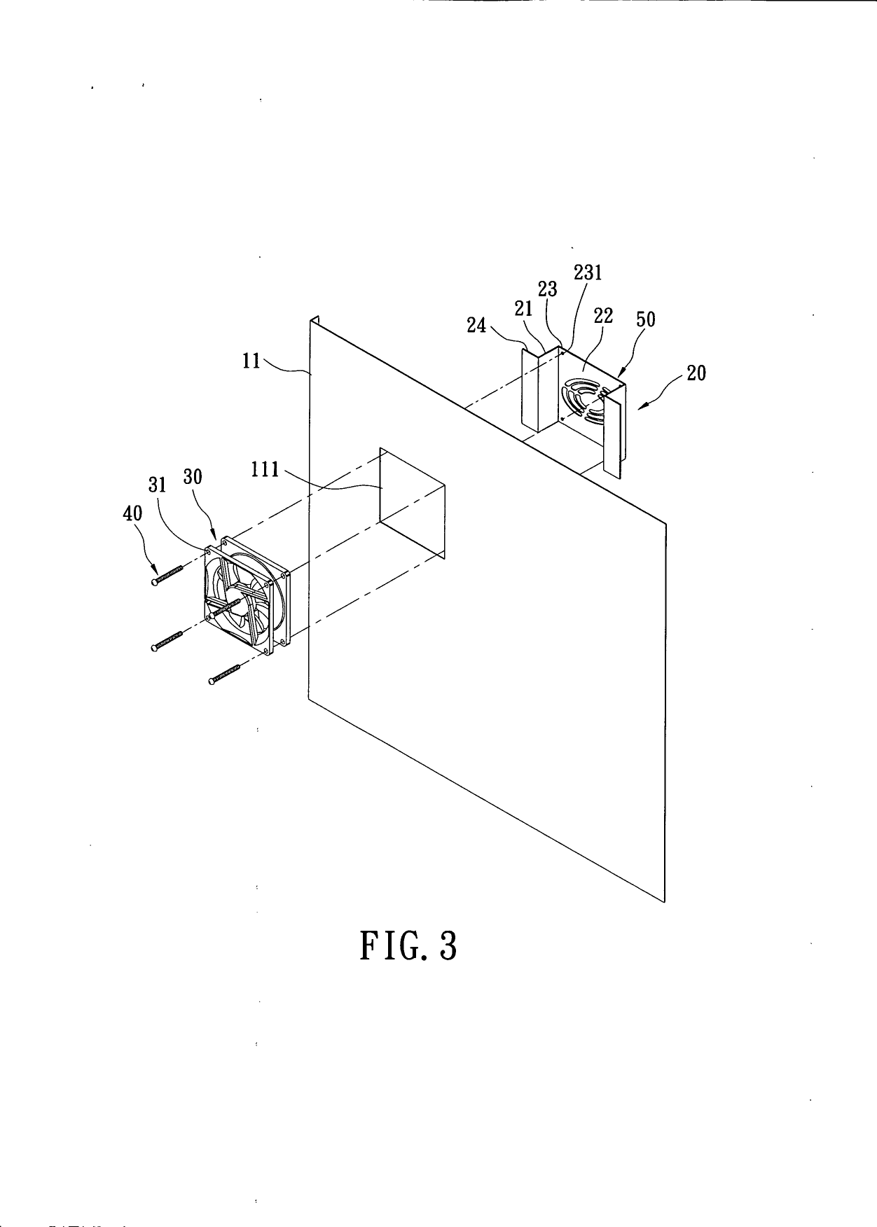

Reference is made to FIG. 3, which is the second embodiment of the present invention. The difference between the second embodiment and the first embodiment is described as followings.

The protection structure 50 is a fan protection screen. The fan protection screen can be formed on the fastening frame 20 into one piece, or is a component that is assembled on the fastening frame 20.

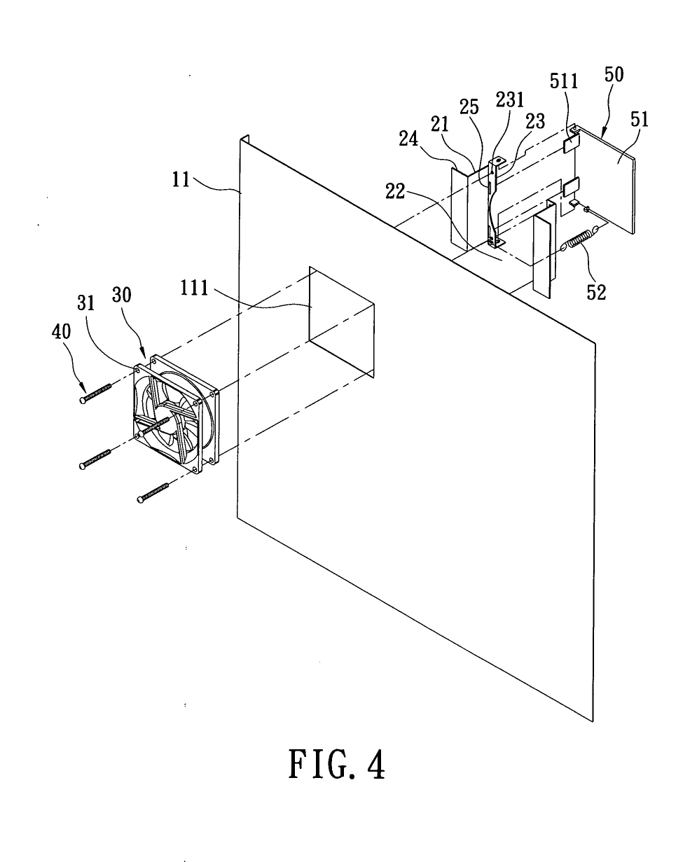

Reference is made to FIG. 4, which is the third embodiment of the present invention. The difference between the third embodiment and the first embodiment is described as followings.

The protection structure 50 includes a rotation door 51 and a flexible unit 52. The rotation door 51 has two pushing blocks 511. The fastening frame 20 has two through holes 25 on the installation portion 23 that correspond to the pushing blocks 511. The two pushing blocks 511 respectively pass through the two through holes 25 and extend into the fan receiving area 22.

The rotation door 51 is pivoted at one side of the fastening frame 20. The flexible unit 52 is connected between the rotation door 51 and the fastening frame 20 so that the rotation door 51 can be opened or closed by utilizing the flexible force of the flexible unit 52.

When the fan 30 is installed into the fan receiving area 22 of the fastening frame 20, the outer frame of the fan 30 will push the pushing blocks 511 of the rotation door 51 to make the two pushing blocks escape from the two through holes 25 to open the rotation door 51. When the fan 30 is disassembled from the fan receiving area 22 of the fastening frame 20, the pushing blocks 511 of the rotation door 51 is not pushed by the outer frame of the fan 30. Therefore, the recovery force provided from the flexible unit 52 closes the rotation door 51 to protect the electronic components in the housing 10.

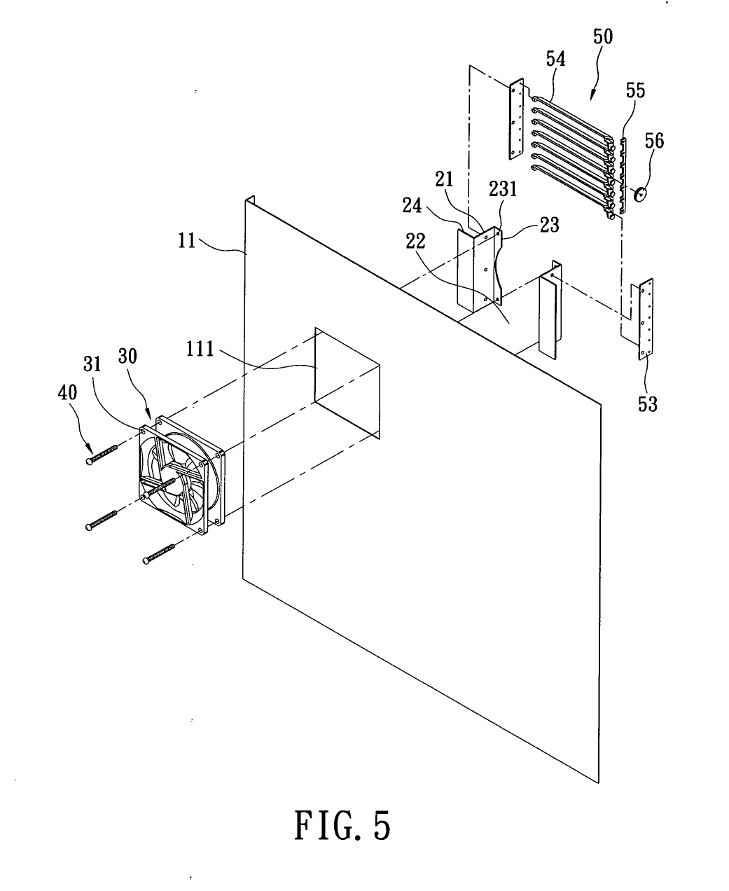

Reference is made to FIG. 5, which is the fourth embodiment of the present invention. The difference between the fourth embodiment and the first embodiment is described as followings.

The protection structure 50 includes two fastening boards 53, a plurality of flow-guiding boards 54, and an adjusting structure that corresponds to the flow-guiding boards 54. The front ends of the two fastening boards 53 are respectively located at the rear side of the two blocking walls 21 of the fastening frame 20. The rear ends of the two fastening boards 53 extends to outside of the two blocking walls 21 and are pivoted with the flow-guiding boards 54 so that the flow-guiding boards 54 can rotate.

In this embodiment, the adjusting structure includes a linking rod 55 and a rotation wheel 56, but not limited to above. The linking rod 55 is located at one side of the flow-guiding boards 54. The flow-guiding boards 54 can synchronously rotate with the linking rod 55 so that the slanting angles of the flow-guiding boards 54 are all the same. The rotation wheel 56 is fastened at right side of one of the flow-guiding boards 54 so that the rotation wheel 56 can synchronously rotate with the flow-guiding board 54.

When the user turns the rotation wheel 56, the rotation wheel 56 makes the flow-guiding board 54 to rotate, and makes the other flow-guiding boards 54 to synchronously rotate via the linking rod 55. Thereby, the slanting angles of the flow-guiding boards 54 are adjusted.

After the fan 30 is disassembled from the housing 10, the flow-guiding boards 54 can prevent the user from touching the electronic components in the housing 10, or prevent dust from entering the housing. The protection effect is achieved.

By using the installation structure for a fan, the fan 30 can be directly disassembled from the housing 10 via the opening 111 to replace or maintain the fan 30. Moreover, after the fan 30 is disassembled, the protection structure 50 prevents the electronic components in the housing 10 from being damaged, such as the user touches the electronic components in the housing 10, or dust enters into the housing 10 to damage the device.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. An installation structure for a fan, comprising:
a housing having an opening;
a fastening frame combined with the housing and having a receiving area, wherein the fan receiving area links to the opening; and
a protection structure combined with the fastening frame.

2. The installation structure for a fan as claimed in claim 1, wherein the housing is a power supply housing, a backup power supply housing, a personal computer housing, industrial computer housing, a server housing, an UPS housing, an external redundant array of independent disk housing, an external hard disk housing, an external optical drive housing, a keyboard housing, a laptop cooling board housing, a projector housing, or a medical measurement test equipment housing.

3. The installation structure for a fan as claimed in claim 1, wherein the fastening frame has at least two blocking walls, the two blocking walls are opposite to each other and are disposed at an interval, there is a fan receiving area between the two blocking walls, one end of each of the blocking walls is connected with a fastening portion, the fastening portion leans against the housing, another end of each of the blocking walls is connected with an installation portion, and the installation portion has a plurality of screw holes.

4. The installation structure for a fan as claimed in claim 1, further comprising a fan, wherein the fan is received in the fan receiving area and installed on the fastening frame via the opening.

5. The installation structure for a fan as claimed in claim 1, wherein the protection structure is a filtering screen.

6. The installation structure for a fan as claimed in claim 1, wherein the protection structure is a fan protection screen.

7. The installation structure for a fan as claimed in claim 1, wherein the protection structure includes a rotation door and a flexible unit, the rotation door is pivoted at one side of the fastening frame, and the flexible unit is connected between the rotation door and the fastening frame so that the rotation door is opened or closed.

8. The installation structure for a fan as claimed in claim 7, wherein the rotation door has a pushing block, the fastening frame has a through hole that corresponds to the pushing block, and the pushing block passes through the through hole and extends into the fan receiving area.

9. The installation structure for a fan as claimed in claim 1, wherein the protection structure includes a plurality of rotation flow-guiding boards, and the flow-guiding boards are located on the fastening frame.

10. The installation structure for a fan as claimed in claim 9, wherein the protection structure further comprises an adjusting structure that corresponds to the flow-guiding boards, and the slanting angles of the flow-guiding boards are adjusted by the adjusting structure.
